(19) United States
(12) Patent Application Publication
(10) Pub. No.: US 2024/0145276 A1
(43) Pub. Date: May 2, 2024

(54) SUBSTRATE CLEANING APPARATUS, SUBSTRATE DRYING APPARATUS, SUBSTRATE TRANSPORT APPARATUS, SUBSTRATE PLACING APPARATUS, SUBSTRATE PROCESSING APPARATUS, CHARGE AMOUNT CONTROL METHOD, AND CHARGE AMOUNT CONTROL PROGRAM

(71) Applicant: EBARA CORPORATION, Tokyo (JP)

(72) Inventor: Yosuke HIMORI, Tokyo (JP)

(21) Appl. No.: 18/497,324

(22) Filed: Oct. 30, 2023

(30) Foreign Application Priority Data
Nov. 2, 2022 (JP) 2022-176235

(51) Int. Cl. H01L 21/67; B08B 1/14; B08B 1/20; B08B 1/34; B08B 3/04; H01L 21/687; H05F 1/00

(52) U.S. Cl. CPC H01L 21/67253; B08B 1/14; B08B 1/20; B08B 1/34; B08B 3/041; H01L 21/67034; H01L 21/67046; H01L 21/68707; H05F 1/00

(57) ABSTRACT

Provided is a substrate cleaning apparatus including: a substrate holding and rotating mechanism configured to hold and rotate a substrate; a cleaning liquid supplier configured to supply a cleaning liquid to the substrate; a cleaning member configured to come into contact with the substrate to clean the substrate; a charge amount adjustment apparatus capable of increasing and decreasing a charge amount of the substrate; a charge amount measuring instrument configured to measure the charge amount of the substrate; and a controller configured to control the charge amount adjustment apparatus according to the charge amount measured by the charge amount measuring instrument.

### CROSS-REFERENCE TO RELATED APPLICATIONS

This application claims the benefit of Japanese Priority Patent Application JP 2022-176235 filed on Nov. 2, 2022, the entire contents of which are incorporated herein by reference.

### FIELD

The present disclosure relates to a substrate cleaning apparatus, a substrate drying apparatus, a substrate transport apparatus, a substrate placing apparatus, a substrate processing apparatus, a charge amount control method, and a charge amount control program.

### BACKGROUND

In a substrate processing apparatus such as a chemical mechanical polishing (CMP), it is known that a metal wiring pattern formed on a surface of a substrate corrodes when the surface of the substrate is charged. As a countermeasure therefor, for example, JP 2012-069550 A discloses a method for manufacturing a semiconductor apparatus including a process of eliminating electricity of a substrate.

### SUMMARY

[1] According to one embodiment, provided is a substrate cleaning apparatus comprising: a substrate holding and rotating mechanism configured to hold and rotate a substrate; a cleaning liquid supplier configured to supply a cleaning liquid to the substrate; a cleaning member configured to come into contact with the substrate to clean the substrate; a charge amount adjustment apparatus capable of increasing and decreasing a charge amount of the substrate; a charge amount measuring instrument configured to measure the charge amount of the substrate; and a controller configured to control the charge amount adjustment apparatus according to the charge amount measured by the charge amount measuring instrument.
[2] The substrate cleaning apparatus according to [1], wherein the controller may control the charge amount adjustment apparatus such that the charge amount measured by the charge amount measuring instrument falls within a target range.
[3] The substrate cleaning apparatus according to [1] or [2], wherein a lower limit value of the target range may be higher than 0.
[4] The substrate cleaning apparatus according to one of [2] and [3], wherein the target range may be determined according to a type of a metal film formed on the substrate.
[5] The substrate cleaning apparatus according to [2] to [4], wherein the controller may determine whether the charge amount measured by the charge amount measuring instrument falls between a first threshold corresponding to the lower limit value of the target range and a second threshold corresponding to an upper limit value of the target range, control the charge amount adjustment apparatus to increase the charge amount of the substrate when it is determined that the charge amount is less than the first threshold, and control the charge amount adjustment apparatus to decrease the charge amount of the substrate when it is determined that the charge amount exceeds the second threshold.
[6] The substrate cleaning apparatus according to one of [1] to [5], wherein the substrate holding and rotating mechanism may have a non-conductive holding member that comes into contact with the substrate and holds the substrate.
[7] The substrate cleaning apparatus according to one of [1] to [5], wherein the substrate holding and rotating mechanism may have a conductive holding member that comes into contact with the substrate and holds the substrate, and the holding member may be coupled to a reference potential terminal via a switch.
[8] The substrate cleaning apparatus according to [7], wherein the controller may control on/off of the charge amount adjustment apparatus and the switch according to the charge amount measured by the charge amount measuring instrument.
[9] The substrate cleaning apparatus according to one of [1] to [8], wherein the controller may control the charge amount adjustment apparatus in a state where the cleaning liquid is supplied and the cleaning member is cleaning the substrate.
[10] According to one embodiment, provided is a substrate drying apparatus comprising: a substrate holding and rotating mechanism configured to hold and rotate a substrate; a fluid supplier configured to supply a fluid for drying the substrate; a charge amount adjustment apparatus capable of increasing and decreasing a charge amount of the substrate; a charge amount measuring instrument configured to measure the charge amount of the substrate; and a controller configured to control the charge amount adjustment apparatus according to the charge amount measured by the charge amount measuring instrument.
[11] According to one embodiment, provided is a substrate transport apparatus that transports a polished substrate, the apparatus comprising: a substrate holding mechanism configured to hold the substrate; a charge amount adjustment apparatus capable of increasing and decreasing a charge amount of the substrate; a charge amount measuring instrument configured to measure the charge amount of the substrate; and a controller configured to control the charge amount adjustment apparatus according to the charge amount measured by the charge amount measuring instrument.
[12] The substrate transport apparatus according to [11], wherein the substrate holding mechanism is provided in an arm that extends and contracts, the charge amount adjustment apparatus is installed at a first position in which the charge amount of the substrate is increased and decreased in both a contracted state and an extended state of the arm, and the charge amount measuring instrument is installed at a second position in which the charge amount of the substrate is measured in both the contracted state and the extended state of the arm.
[13] According to one embodiment, provided is a substrate placing apparatus comprising: a substrate holding mechanism configured to hold a substrate; a liquid supplier configured to supply a liquid to the substrate; a charge amount adjustment apparatus capable of increasing and decreasing a charge amount of the substrate; a charge amount measuring instrument configured to measure the charge amount of the substrate; and a controller configured to control the charge amount adjustment apparatus according to the charge amount measured by the charge amount measuring instrument.
[14] According to one embodiment, provided is a substrate processing apparatus comprising: a substrate polishing apparatus configured to polish a substrate; the substrate cleaning apparatus according to one of [1] to [7] configured to clean the polished substrate; the substrate drying apparatus according to configured to dry the cleaned substrate; a first substrate transport apparatus that is the substrate transport apparatus according to or configured to transport the substrate from the substrate polishing apparatus to the substrate cleaning apparatus; and a second substrate transport apparatus that is the substrate transport apparatus according to or configured to transport the substrate from the substrate cleaning apparatus to the substrate drying apparatus.
[15] According to one embodiment, provided is a charge amount control method during substrate cleaning, the method comprising: a step of supplying a cleaning liquid to a rotating substrate and measuring a charge amount of the substrate while cleaning the substrate by bringing a cleaning member into contact with the substrate; and a step of controlling a charge amount adjustment apparatus capable of increasing and decreasing the charge amount of the substrate according to the measured charge amount.
[16] According to one embodiment, provided is a charge amount control method during substrate drying, the method comprising: a step of measuring a charge amount of a rotating substrate while supplying a fluid for drying the substrate to the substrate; and a step of controlling a charge amount adjustment apparatus capable of increasing and decreasing the charge amount of the substrate according to the measured charge amount.
[17] According to one embodiment, provided is a charge amount control method during substrate transport, the method comprising: a step of measuring a charge amount of a substrate while transporting the substrate after polishing; and a step of controlling a charge amount adjustment apparatus capable of increasing and decreasing the charge amount of the substrate according to the measured charge amount.
[18] According to one embodiment, provided is a charge amount control method during substrate placing, the method comprising: a step of measuring a charge amount of a held substrate while supplying a liquid to the substrate after polishing; and a step of controlling a charge amount adjustment apparatus capable of increasing and decreasing the charge amount of the substrate according to the measured charge amount.
[19] According to one embodiment, provided is a substrate processing method comprising: a step of polishing a substrate by a substrate polishing apparatus; a step of transporting the substrate after polishing from the substrate polishing apparatus to a substrate cleaning apparatus, the step including each step in the charge amount control method during substrate transport according to [17]; a step of cleaning the substrate by the substrate cleaning apparatus, the step including each step in the charge amount control method during substrate cleaning according to [15]; a step of transporting the substrate after cleaning from the substrate cleaning apparatus to a substrate drying apparatus, the step including each step in the charge amount control method during substrate transport according to [17]; and a step of drying the substrate by the substrate drying apparatus, the step including each step in the charge amount control method during substrate drying according to [16].
[20] According to one embodiment, provided is a charge amount control program during substrate cleaning, causing a computer to execute: a step of acquiring a charge amount of a rotating substrate measured in a state where a cleaning liquid is supplied to the substrate and the substrate is cleaned by bringing a cleaning member into contact with the substrate; and a step of controlling a charge amount adjustment apparatus capable of increasing and decreasing the charge amount of the substrate according to the acquired charge amount.
[21] According to one embodiment, provided is a charge amount control program during substrate drying, causing a computer to execute: a step of acquiring a charge amount of a rotating substrate measured in a state where a fluid for drying the substrate is supplied to the substrate; and a step of controlling a charge amount adjustment apparatus capable of increasing and decreasing the charge amount of the substrate according to the acquired charge amount.
[22] According to one embodiment, provided is a charge amount control program during substrate transport, causing a computer to execute: a step of acquiring a charge amount of a substrate measured in a state where the substrate after polishing is transported; and a step of controlling a charge amount adjustment apparatus capable of increasing and decreasing the charge amount of the substrate according to the acquired charge amount.
[23] According to one embodiment, provided is a charge amount control program during substrate placing, causing a computer to execute: a step of acquiring a charge amount of a held substrate measured in a state where a liquid is supplied to the substrate after polishing; and a step of controlling a charge amount adjustment apparatus capable of increasing and decreasing the charge amount of the substrate according to the acquired charge amount.

### BRIEF DESCRIPTION OF DRAWINGS

FIG. 1 is a graph illustrating a result of measuring a metal loss amount when a charge amount of a substrate surface is changed;

FIG. 2 is a schematic configuration view of a substrate processing apparatus;

FIG. 3A is a view schematically illustrating an example of a substrate cleaning apparatus;

FIG. 3B is a view schematically illustrating a substrate cleaning apparatus which is a modification of FIG. 3A;

FIG. 4 is a block view illustrating an internal configuration of a controller;

FIG. 5 is a flowchart illustrating an example of a processing operation by the controller;

FIG. 6 is a view schematically illustrating a specific example of charge amount adjustment;

FIG. 7 is a view schematically illustrating another example of the substrate cleaning apparatus;

FIG. 8 is a view schematically illustrating a specific example of the charge amount adjustment;

FIG. 9 is a view schematically illustrating an example of a substrate drying apparatus;

FIG. 10A is a view schematically illustrating an example of a substrate transport apparatus;

FIG. 10B is a view schematically illustrating an example of the substrate transport apparatus;

FIG. 11 is a view schematically illustrating an example of a substrate placing apparatus; and

FIG. 12 is a flowchart illustrating an overall operation of the substrate processing apparatus.

### DETAILED DESCRIPTION

When a charge amount of a surface of a substrate is large, a metal film formed on the surface of the substrate corrodes. This is because an anode reaction (the following formula (1)) or a cathode reaction (the following formula (2)) occurs due to a large separation of a surface potential from a natural potential, so that a pair reaction also occurs. In addition, according to the study of the inventors, it has been found that the metal film corrodes even when the charge amount of the surface of the substrate is too small. The reason for this is considered to be that, in a case of a chemical liquid having a large oxidation-reduction potential, a potential difference on a metal surface increases and a corrosion reaction proceeds.

Cu→Cy²⁺+3e⁻ (1)

½O₂+H₂O+2e⁻→2OH⁻ (2)

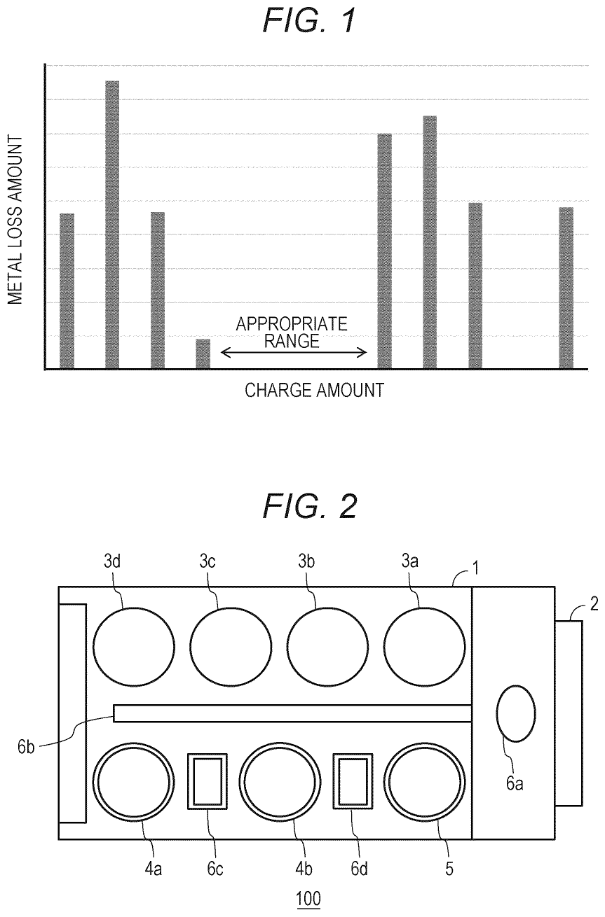

The inventors have experimentally confirmed that corrosion can be suppressed by controlling a charge amount within an appropriate range. For example, FIG. 1 is a graph illustrating a result of measuring a metal loss amount of Cu in a case where a charge amount of a substrate surface is changed. As illustrated in the drawing, the metal loss amount (corrosion) can be suppressed by setting the charge amount on the surface of the substrate within an appropriate range. Then, the inventors have found that it is desirable to make a lower limit value of the appropriate range higher than 0 kV (that is, the charge is not completely eliminated or negatively charged, but slightly positively charged).

Therefore, the present specification discloses a technique for suppressing corrosion of a metal film formed on a surface of a substrate by controlling a charge amount of the surface of the substrate to fall within an appropriate range. Hereinafter, an embodiment according to the present invention will be specifically described with reference to the drawings.

[Overall Configuration of Substrate Processing Apparatus 100]

FIG. 2 is a schematic configuration view of a substrate processing apparatus 100. The substrate processing apparatus 100 is, for example, a CMP apparatus, and includes a substantially rectangular housing 1 and a load port 2 disposed adjacent to the housing 1.

A substrate cassette (not illustrated) for stocking a plurality of substrates W is placed on the load port 2. Examples of the substrate W include a semiconductor wafer. However, the substrate W to be processed is not limited to the semiconductor wafer, and may be another type of substrate used for manufacturing a semiconductor apparatus such as a glass substrate or a ceramic substrate. In addition, a metal film of Cu, Co, Mo, or the like is formed on at least one plane of the substrate W. Hereinafter, the plane on which the metal film is formed is referred to as a surface.

The substrate processing apparatus 100 includes one or more (four in FIG. 1) substrate polishing apparatuses 3a to 3d (when they are not particularly distinguished, they may be collectively referred to as a “substrate polishing apparatus 3”), one or more (two in FIG. 1) substrate cleaning apparatuses 4a and 4b (when they are not particularly distinguished, they may be collectively referred to as a “substrate cleaning apparatus 4”), and one or more (one in FIG. 1) substrate drying apparatuses 5, which are disposed inside the housing 1.

As an example, the substrate polishing apparatuses 3a to 3d are disposed along one side of the housing 1 in a longitudinal direction. The substrate cleaning apparatuses 4a and 4b and the substrate drying apparatus 5 are disposed along the other side of the housing 1 in the longitudinal direction.

The substrate polishing apparatus 3 polishes the surface of the substrate W. More specifically, the substrate polishing apparatus 3 polishes the surface of the substrate W by pressing a polishing member (not illustrated) against the surface of the substrate W while rotating the substrate W. The surface of the substrate W may be charged during polishing due to friction between the substrate W and the polishing member.

The substrate cleaning apparatus 4 cleans the surface of the polished substrate W. More specifically, the substrate cleaning apparatus 4 cleans the surface of the substrate W by pressing a cleaning member (not illustrated) against the surface of the substrate W while rotating the substrate W. Therefore, the surface of the substrate W may be charged during cleaning. In the present embodiment, a charge amount control mechanism can be provided in the substrate cleaning apparatus 4. A configuration example of the substrate cleaning apparatus 4 will be described later.

The substrate drying apparatus 5 dries the surface of the cleaned substrate W. In the present embodiment, a charge amount control mechanism can be provided in the substrate cleaning apparatus 4. A configuration example of the substrate drying apparatus 5 will also be described later.

In addition, the substrate processing apparatus 100 includes substrate transport apparatuses 6a to 6d (when they are not particularly distinguished, they may be collectively referred to as a “substrate transport apparatus 6”), which are disposed inside the housing 1.

The substrate transport apparatus 6a is disposed adjacent to the load port 2. The substrate transport apparatus 6a receives an unprocessed substrate W from the load port 2 and transfers the substrate W to the substrate transport apparatus 6b, or receives a processed substrate W from the substrate transport apparatus 6b.

The substrate transport apparatus 6b extends in the longitudinal direction at a central portion of the housing 1. The substrate transport apparatus 6b receives an unprocessed substrate W from the substrate transport apparatus 6a and transports the substrate W to any one of the substrate polishing apparatuses 3a to 3d, receives a substrate W after polishing from the substrate polishing apparatuses 3a to 3d and transfers the substrate W to the substrate transport apparatus 6c, or receives a dried substrate W from the substrate transport apparatus 6d and transfers the substrate W to the substrate transport apparatus 6a.

The substrate transport apparatus 6c is disposed between the substrate cleaning apparatuses 4a and 4b. The substrate transport apparatus 6c receives a polished substrate W from the substrate transport apparatus 6b and transports the substrate W to either the substrate cleaning apparatus 4a or 4b, or receives a substrate W after cleaning from the substrate cleaning apparatus 4a and transports the substrate W to the substrate cleaning apparatus 4b.

The substrate transport apparatus 6d is disposed between the substrate cleaning apparatus 4b and the substrate drying apparatus 5. The substrate transport apparatus 6d receives a substrate W after cleaning from the substrate cleaning apparatus 4b and transports the substrate W to the substrate drying apparatus 5, or receives a substrate W after drying from the substrate drying apparatus 5 and transfers the substrate W to the substrate transport apparatus 6b.

Note that arrangement of the substrate polishing apparatus 3, the substrate cleaning apparatus 4, the substrate drying apparatus 5, and the substrate transport apparatus 6 is merely an example. One or more substrate transport apparatuses 6 may be provided so that the substrate W can be transported in the order of the substrate polishing apparatus 3, the substrate cleaning apparatus 4, and the substrate drying apparatus 5. In the present embodiment, a charge amount control mechanism can be provided in the substrate transport apparatus 6 that transports the polished substrate W. A configuration example of the substrate transport apparatus 6 will be described later.

[Configuration Example of Substrate Cleaning Apparatus 4]

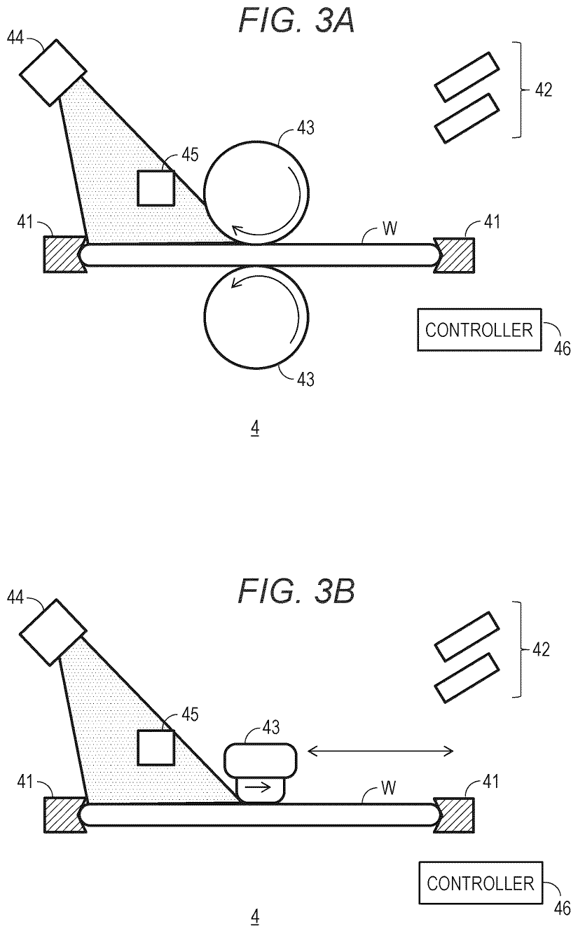

FIG. 3A is a view schematically illustrating an example of the substrate cleaning apparatus 4. The substrate cleaning apparatus 4 has a substrate holding and rotating mechanism 41, cleaning liquid supply nozzles 42, a cleaning member 43, a charge amount adjustment apparatus 44, a charge amount measuring instrument 45, and a controller 46.

The substrate holding and rotating mechanism 41 holds and rotates the substrate W. As a specific example, the substrate holding and rotating mechanism 41 holds the substrate W in a horizontal direction and rotates the substrate W with a vertical axis passing through a center of the substrate W as a rotation axis. As another example, the substrate holding and rotating mechanism 41 may hold the substrate W in the vertical direction and rotate the substrate W with a horizontal axis passing through the center of the substrate W as a rotation axis.

The substrate holding and rotating mechanism 41 desirably holds the substrate W with a non-conductive holding member. As a specific example, the substrate holding and rotating mechanism 41 has a non-conductive chuck (holding member) made of urethane or the like, and the chuck holds the substrate W by coming into contact with the substrate W. When the chuck is non-conductive, charges accumulated on the surface of the substrate W hardly discharge via the chuck. Therefore, adjustment of a charge amount described later becomes easy.

The cleaning liquid supply nozzle 42 supplies a cleaning liquid to the surface (that is, a plane on which the metal film is formed) of the substrate W. The cleaning liquid supply nozzle 42 may include at least one of a pure water nozzle for supplying pure water and a chemical liquid nozzle for supplying a chemical liquid. When the cleaning liquid is supplied to the surface of the substrate W, the electric charge amount on the substrate W can be changed.

The cleaning member 43 comes into contact with the surface of the substrate W to clean the substrate W. As illustrated in FIG. 3A, the cleaning member 43 may be a roll sponge type. The roll sponge type cleaning member 43 comes into contact with the surface of the rotating substrate W (the rotation speed is, for example, 100 to 200 rpm) while rotating with the longitudinal direction thereof as a rotation axis.

As illustrated in FIG. 3B as a modification of FIG. 3A, the cleaning member 43 may be a pencil type. The pencil type cleaning member 43 rotates in a plane parallel to the substrate W and swings between a center and an edge of the rotating substrate W (the rotation speed is, for example, 1000 to 2000 rpm) to come into contact with the surface of the substrate W. Note that the configuration of the substrate cleaning apparatus 4 illustrated in FIG. 3B other than the cleaning member 43 may be similar to that of the substrate cleaning apparatus 4 illustrated in FIG. 3A.

The cleaning member 43 is made of, for example, PVA, and the electric charge amount on the surface of the substrate W increases by coming into contact with the rotating substrate W.

The charge amount adjustment apparatus 44 can increase or decrease the charge amount of the surface of the substrate W according to control from the controller 46 described later. As the charge amount adjustment apparatus 44, a known apparatus may be applied. Alternatively, the charge amount adjustment apparatus 44 may include a charger (for example, a known ionizer) that increases the charge amount and a discharger (for example, a known corona discharger) that decreases the charge amount.

The arrangement position of the charge amount adjustment apparatus 44 is not particularly limited, and is disposed at an arbitrary position in which the charge amount of the surface of the substrate W can be adjusted, for example, about 30 cm above the substrate W. Desirably, the charge amount adjustment apparatus 44 is disposed immediately above the substrate W so that the charge amount can be quickly adjusted. In addition, since the substrate W is rotating, the charge amount adjustment apparatus 44 does not necessarily have to be able to adjust the charge amount of the entire surface of the substrate W. For example, it is sufficient that the charge amount in a part of the substrate W, such as a left half of the cleaning member 43 in FIG. 3A, can be adjusted. In addition, the number of charge amount adjustment apparatuses 44 to be provided is not particularly limited.

The charge amount measuring instrument 45 measures the charge amount of the surface of the substrate W. The measured charge amount is transmitted to the controller 46. As the charge amount measuring instrument 45, a known instrument may be applied. The arrangement position of the charge amount measuring instrument 45 is not particularly limited, and is disposed at an arbitrary position in which the charge amount of the surface of the substrate W can be measured. Since the substrate W is rotating, the charge amount measuring instrument 45 only needs to be able to measure the charge amount in a region of a certain area of the substrate W, and does not need to measure the charge amount on the entire surface or the charge amount in a minute region. In addition, the number of charge amount measuring instruments 45 to be provided is not particularly limited. However, in a case where a plurality of the charge amount measuring instruments 45 are provided, it is desirable to dispose such that the charge amounts of a plurality of regions arranged on the surface of the substrate W in a radial direction can be measured.

The controller 46 is coupled to the charge amount adjustment apparatus 44 and the charge amount measuring instrument 45, and controls the charge amount adjustment apparatus 44 according to the charge amount measured by the charge amount measuring instrument 45. Specifically, the controller 46 controls the charge amount adjustment apparatus 44 such that the charge amount measured by the charge amount measuring instrument 45 falls within a target range.

The target range is a charge amount by which corrosion of the metal film formed on the surface of the substrate W is suppressed, and is experimentally determined in advance, for example, according to a type of a film formed on the surface of the substrate W.

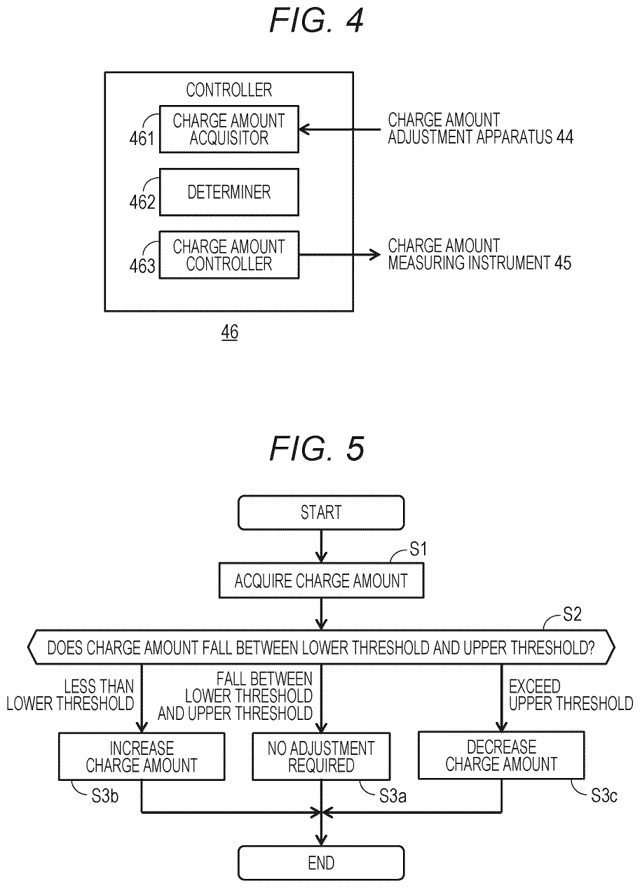

FIG. 4 is a block view illustrating an internal configuration of the controller 46. The controller 46 has a charge amount acquisitor 461, a determiner 462, and a charge amount controller 463. The controller 46 may be a dedicated apparatus or a general-purpose computer such as a personal computer. Furthermore, each unit in the controller 46 may be implemented by hardware or may be implemented by software. In the latter case, the functions of the respective units may be implemented by a processor of the computer executing a predetermined program.

The charge amount acquisitor 461 acquires the charge amount measured by the charge amount measuring instrument 45. The determiner 462 determines whether it is necessary to adjust the charge amount of the substrate W based on the acquired charge amount. When it is determined that adjustment is necessary, the charge amount controller 463 controls the charge amount adjustment apparatus 44 so as to increase or decrease the charge amount of the substrate W.

FIG. 5 is a flowchart illustrating an example of a processing operation by the controller 46. It is assumed that the target range is determined in advance according to the type of the metal film formed on the surface of the substrate W.

The charge amount acquisitor 461 acquires a charge amount of the substrate W measured by the charge amount measuring instrument 45 (step S1).

Then, the determiner 462 determines whether it is necessary to adjust the charge amount based on the acquired charge amount and the target range. As a specific example, the determiner 462 determines whether the acquired charge amount falls between a lower threshold corresponding to a lower limit value of the target range and an upper threshold corresponding to an upper limit value of the target range (step S2).

The lower threshold may be the lower limit value itself of the target range, may be higher than the lower limit value by a predetermined value, or may be lower than the lower limit value by a predetermined value. The upper threshold may be the upper limit value itself of the target range, may be lower than the upper limit value by a predetermined value, or may be higher than the lower limit value by a predetermined value.

Note that, in a case where a plurality of charge amount acquisitors 461 are provided, the determination in step S2 may be determination of whether a statistical value (average value, median value, or the like) of the acquired charge amount falls between the upper threshold and the lower threshold. Alternatively, it may be determined whether a maximum value of the acquired charge amount exceeds the upper threshold and whether a minimum value of the acquired charge amount is less than the lower threshold.

When it is determined that the acquired charge amount falls between the lower threshold and the upper threshold, it is not necessary to adjust the charge amount of the substrate W (step S3a). When it is determined that the acquired charge amount is less than the lower threshold, the charge amount controller 463 controls the charge amount adjustment apparatus 44 such that the charge amount of the substrate W increases (step S3b). When it is determined that the acquired charge amount exceeds the upper threshold, the charge amount controller 463 controls the charge amount adjustment apparatus 44 such that the charge amount of the substrate W decreases (step S3c).

When the lower threshold is set higher than the lower limit value of the target range, adjustment for increasing the charge amount is performed before the charge amount becomes less than the target range, and the charge amount is suppressed from becoming less than the target range. When the charge amount is allowed to be slightly less than a target value, the lower threshold may be the lower limit value itself of the target range or may be slightly lower than the lower limit value. The same applies to the upper threshold.

The above control is performed every time the charge amount is acquired. The timing of acquiring the charge amount is arbitrary, and may be, for example, at regular time intervals. In addition, the above control is desirably performed in a state where the cleaning liquid is supplied and the cleaning member 43 is cleaning the substrate W. This is because the charge amount on the substrate W changes from moment to moment due to friction between the cleaning member 43 and the substrate W or supply of the cleaning liquid, but the charge amount can be controlled in real time.

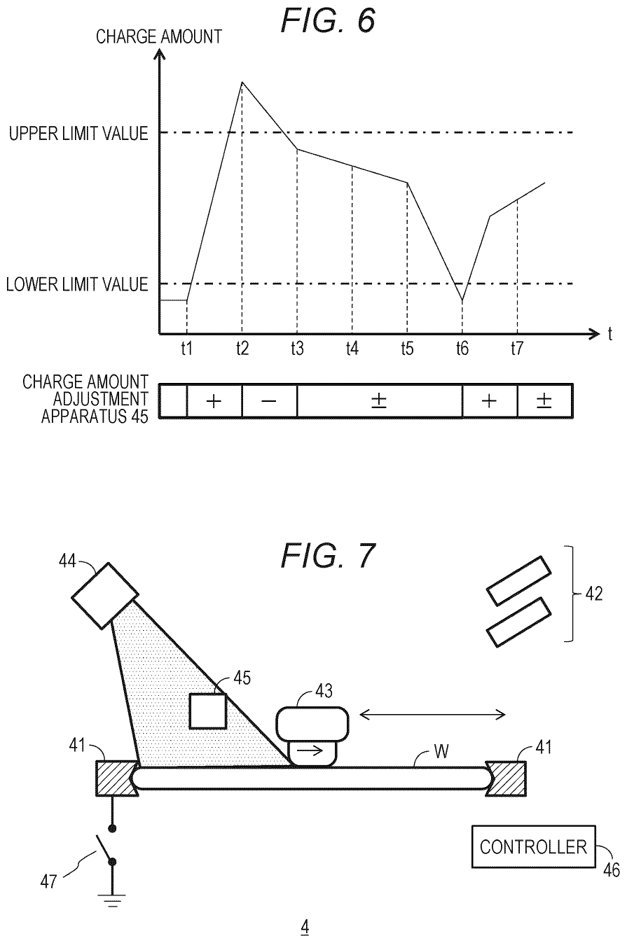

FIG. 6 is a view schematically illustrating a specific example of charge amount adjustment. A horizontal axis represents a passage of time. Time t1 to time t7 indicate timings at which the controller 46 acquires a charge amount from the charge amount measuring instrument 45. A vertical axis represents an electric charge amount of on the surface of the substrate W. In order to simplify the description, it is assumed that an upper threshold is an upper limit value of a target range, and a lower threshold is a lower limit value of the target range.

At time t1, a charge amount is less than the lower limit value. Therefore, the controller 46 controls the charge amount adjustment apparatus 44 so as to increase the charge amount. As a result, the charge amount increases.

At time t2, the charge amount exceeds the upper limit value. Therefore, the controller 46 controls the charge amount adjustment apparatus 44 so as to decrease the charge amount. As a result, the charge amount decreases.

At time t3, the charge amount falls between the upper limit value and the lower limit value. Therefore, the controller 46 controls the charge amount adjustment apparatus 44 so as not to increase or decrease the charge amount. Even when the charge amount adjustment apparatus 44 does not increase or decrease the charge amount, the electric charge amount may decrease due to discharge of charges, or the electric charge amount may increase due to friction between the cleaning member 43 and the substrate W.

Also, at times t4 and t5, the charge amounts fall between the upper limit value and the lower limit value. Therefore, the controller 46 controls the charge amount adjustment apparatus 44 so as not to increase or decrease the charge amount. At time t5, it is indicated that the electric charge amount has greatly decreased as a predetermined process has occurred.

At time t6, the charge amount is less than the lower limit value. Therefore, the controller 46 controls the charge amount adjustment apparatus 44 so as to increase the charge amount. As a result, the charge amount increases.

At time t7, the charge amount falls between the upper limit value and the lower limit value. Therefore, the controller 46 controls the charge amount adjustment apparatus 44 so as not to increase or decrease the charge amount.

By such control, the charge amount of the substrate W can be adjusted so as not to greatly deviate from the target range.

According to the substrate cleaning apparatus 4 described above, the corrosion of the metal film formed on the surface of the substrate W can be suppressed since the charge amount of the substrate W is appropriately adjusted.

[Another Configuration Example of Substrate Cleaning Apparatus 4]

Next, another configuration example of the substrate cleaning apparatus 4 will be described. Hereinafter, description of matters common to the points described in FIGS. 3A to 6 will be omitted.

FIG. 7 is a view schematically illustrating another example of the substrate cleaning apparatus 4. As a difference from FIG. 3A, the substrate holding and rotating mechanism 41 has a conductive chuck (holding member) made of a conductive PEEK or the like, and the chuck comes into contact with and holds the substrate W. The substrate cleaning apparatus 4 has a switch 47. The chuck is coupled to a ground terminal (reference voltage terminal) via the switch 47. When there are a plurality of chucks, the switch 47 may be provided in each of the chucks, or a plurality of chucks may be electrically coupled to each other, and one switch 47 common to the plurality of chucks may be provided.

In this example, when the switch 47 is turned on, the chuck is electrically coupled to the ground terminal. As a result, the substrate W is grounded, and the charge on the substrate W is discharged from the ground terminal. On the other hand, when the switch 47 is turned off, the chuck is insulated from the ground terminal. In this state, as in the case where the chuck is non-conductive, the charge on the substrate W is hardly discharged via the chuck. The switch 47 is controlled by the controller 46.

The internal configuration of the controller 46 is similar to that illustrated in FIG. 4. However, the charge amount controller 463 controls on/off of the switch 47 according to the charge amount acquired by the charge amount acquisitor 461. That is, the controller 46 controls the charge amount adjustment apparatus 44 and/or the switch 47 such that the charge amount falls within the target range according to the charge amount acquired by the charge amount acquisitor 461.

The processing operation of the controller 46 is similar to that illustrated in FIG. 5. However, in step S3c, in order to decrease the charge amount, the charge amount controller 463 may control the charge amount adjustment apparatus 44, may turn on the switch 47, or may control the charge amount adjustment apparatus 44 and turn on the switch 47. Since a response speed of the electric charge amount is faster in the case of discharge via the switch 47, it is desirable to turn on the switch 47 to quickly decrease the electric charge amount and to supplementarily decrease the electric charge amount by the charge amount adjustment apparatus 44.

Note that, as a matter of course, the switch 47 is turned off except when the charge amount is decreased.

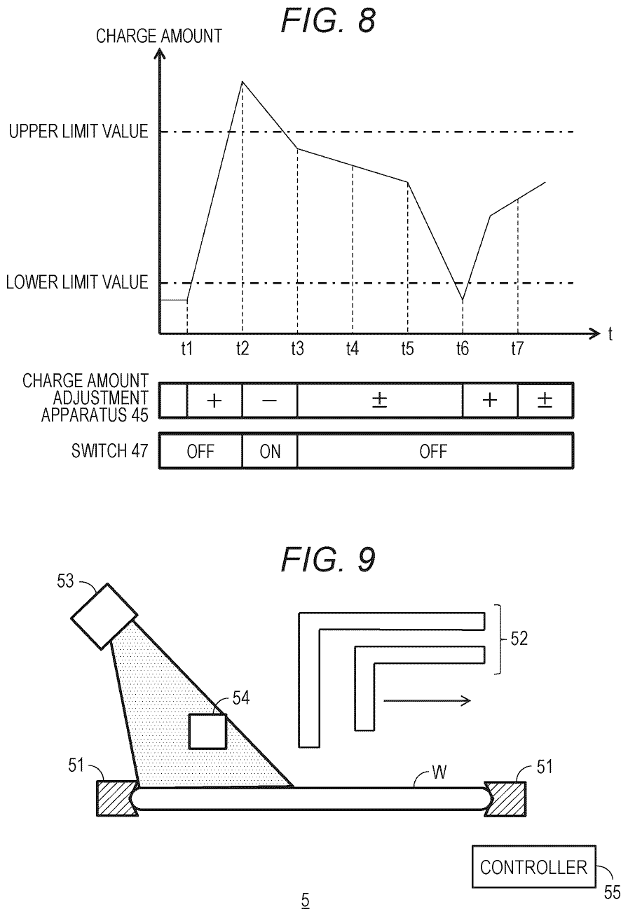

FIG. 8 is a view schematically illustrating a specific example of the charge amount adjustment. As a difference from FIG. 6, at time t2 to time t3, in order to decrease the charge amount, the charge amount adjustment apparatus 44 may decrease the charge amount, and the switch 47 may be turned on to discharge the charge on the substrate W from the ground terminal, thereby decreasing the charge amount.

Since the switch 47 decreases the charge on the substrate W, it can be considered that the charge amount adjustment apparatus 44 has the switch 47. In this case, the charge amount adjustment apparatus 44 may include a charger for increasing the charge amount and a switch 47 for decreasing the charge amount.

In the example described above, the chuck is coupled to the ground terminal via the switch 47, but may be coupled to a terminal (reference potential terminal) to which a predetermined potential is supplied. In a case where a positive potential is supplied to this terminal, the switch 47 may be turned on in a case where the charge amount is increased.

According to the substrate cleaning apparatus 4 described above, since the charge amount of the substrate W can be appropriately adjusted even when the chuck of the substrate holding and rotating mechanism 41 is conductive, corrosion of the metal film formed on the surface of the substrate W can be suppressed.

[Configuration Example of Substrate Drying Apparatus 5]

FIG. 9 is a view schematically illustrating an example of the substrate drying apparatus 5. Hereinafter, the matters common to those of the substrate cleaning apparatus 4 described above may be omitted or simplified. The substrate drying apparatus 5 has a substrate holding and rotating mechanism 51, drying fluid supply nozzles 52, a charge amount adjustment apparatus 53, a charge amount measuring instrument 54, and a controller 55.

The substrate holding and rotating mechanism 51 is similar to the substrate holding and rotating mechanism 41 in FIG. 3A, and holds and rotates the substrate W. The substrate holding and rotating mechanism 51 desirably holds the substrate W with a non-conductive chuck.

The drying fluid supply nozzle 52 supplies one or more fluids for drying the surface (that is, a plane on which the metal film is formed) of the substrate W. The drying fluid supply nozzle 52 may include a pure water nozzle for supplying pure water and an isopropyl alcohol (IPA) nozzle for supplying IPA.

These nozzles are held by an arm and swing above the substrate W.

The charge amount adjustment apparatus 53 is similar to the charge amount adjustment apparatus 44 of FIG. 3A, and can increase or decrease the charge amount of the surface of the substrate W according to the control from the controller 55 described later.

The charge amount measuring instrument 54 is similar to the charge amount measuring instrument 45 of FIG. 3A, and measures the charge amount of the surface of the substrate W. The measured charge amount is transmitted to the controller 55.

The controller 55 is similar to the controller 46 in FIG. 3A, is coupled to the charge amount adjustment apparatus 53 and the charge amount measuring instrument 54, and controls the charge amount adjustment apparatus 53 according to the charge amount measured by the charge amount measuring instrument 54.

The internal configuration of the controller 55 is similar to that illustrated in FIG. 4. The processing operation of the controller 55 is similar to that illustrated in FIG. 5. The control by the controller 55 is desirably performed in a state where a fluid (particularly pure water) for drying the substrate W is supplied. This is because the charge amount on the substrate W changes from moment to moment due to the supply of the fluid, but the charge amount can be controlled in real time.

When the chuck of the substrate holding and rotating mechanism 51 is conductive, the chuck may be coupled to the ground terminal via a switch as in FIG. 7.

[Configuration Example of Substrate Transport Apparatus 6]

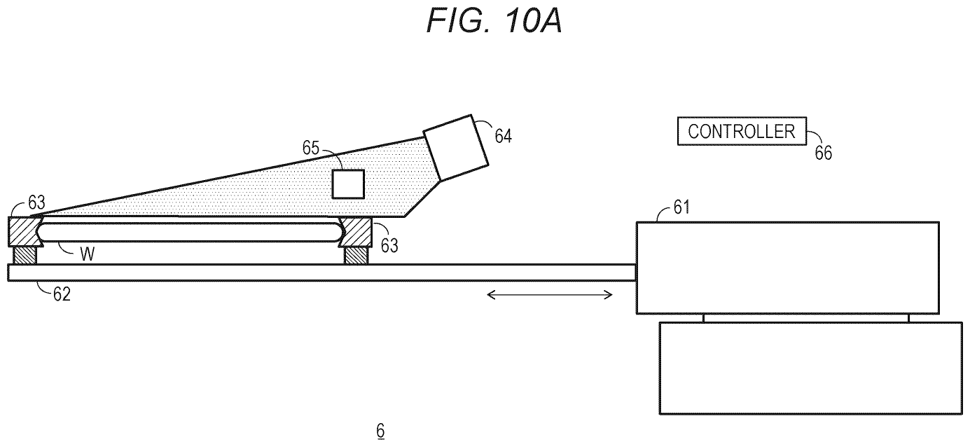

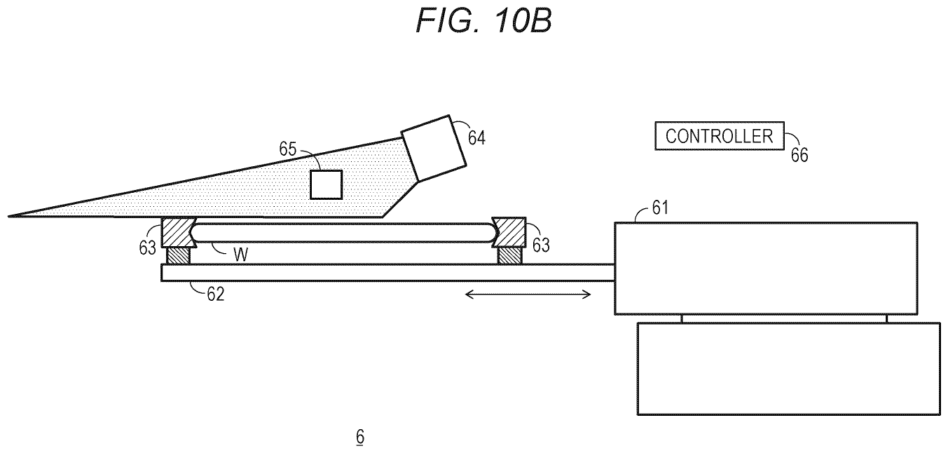

FIGS. 10A and 10B are views schematically illustrating an example of the substrate transport apparatus 6. Hereinafter, the matters common to those of the substrate cleaning apparatus 4 described above may be omitted or simplified. The substrate transport apparatus 6 has a transport robot 61, an arm 62, a substrate holding mechanism 63, a charge amount adjustment apparatus 64, a charge amount measuring instrument 65, and a controller 66.

The transport robot 61 transports the held substrate W to a desired position by moving, rotating, or extending and contracting the arm 62 described later.

The arm 62 is coupled to the transport robot 61 and extends in the horizontal direction. The arm 62 is extendable and contractable in the horizontal direction. FIG. 10A illustrates a state in which the arm 62 is extended, and FIG. 10B illustrates a state in which the arm 62 is contracted.

The substrate holding mechanism 63 is fixed to the arm 62 and holds the substrate W. As a specific example, the substrate holding mechanism 63 holds the substrate W in the horizontal direction. The substrate holding mechanism 63 desirably holds the substrate W with a non-conductive chuck. As the arm 62 extends and contracts, the substrate holding mechanism 63 moves, and the held substrate W also moves accordingly.

The charge amount adjustment apparatus 64 is similar to the charge amount adjustment apparatus 44 of FIG. 3A, and can increase or decrease the charge amount of the surface of the substrate W according to the control from the controller 66 described later. The charge amount adjustment apparatus 64 may be configured to follow the extension and contraction of the arm 62, but may be fixed at a predetermined position in order to simplify the apparatus configuration. In the latter case, it is desirable that the charge amount adjustment apparatus 64 is installed at a position in which the charge amount can be adjusted regardless of whether the arm 62 is in the extended state or the contracted state.

The charge amount measuring instrument 65 is similar to the charge amount measuring instrument 45 of FIG. 3A, and measures the charge amount of the surface of the substrate W. The measured charge amount is transmitted to the controller 66. The charge amount measuring instrument 65 may be configured to follow the extension and contraction of the arm 62, but may be fixed at a predetermined position in order to simplify the apparatus configuration. In the latter case, it is desirable that the charge amount measuring instrument 65 is installed at a position in which the charge amount can be measured regardless of whether the arm 62 is in the extended state or the contracted state.

The controller 66 is similar to the controller 46 in FIG. 3A, is coupled to the charge amount adjustment apparatus 64 and the charge amount measuring instrument 65, and controls the charge amount adjustment apparatus 64 according to the charge amount measured by the charge amount measuring instrument 65.

The internal configuration of the controller 66 is similar to that illustrated in FIG. 4. The processing operation of the controller 66 is similar to that illustrated in FIG. 5. The control by the controller 66 is desirably performed while transporting the substrate W in a state where a liquid (for example, pure water) remains on the substrate W. This is because the charge amount can be controlled in real time although the charge amount on the substrate W changes from moment to moment as the liquid on the substrate W moves along with the transport of the substrate W.

When the chuck of the substrate holding mechanism 63 is conductive, the chuck may be coupled to the ground terminal via a switch as in FIG. 7.

[Configuration Example of Substrate Placing Apparatus]

Although not illustrated in FIG. 1, the substrate processing apparatus 100 may include a substrate placing apparatus 7 (wafer station) on which the polished substrate W can be placed. The substrate placing apparatus 7 may be provided with a charge amount control mechanism. Hereinafter, description of matters common to the points described in FIGS. 3A to 6 will be omitted.

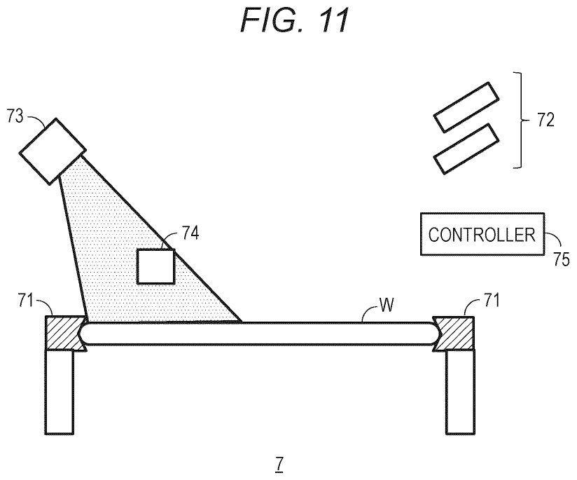

FIG. 11 is a view schematically illustrating an example of the substrate placing apparatus 7. The substrate placing apparatus 7 has a substrate holding mechanism 71, liquid supply nozzles 72, a charge amount adjustment apparatus 73, and a charge amount measuring instrument 74.

The substrate holding mechanism 71 holds the substrate W. As a specific example, the substrate holding mechanism 71 holds the substrate W in the horizontal direction. The substrate holding mechanism 71 desirably holds the substrate W with a non-conductive chuck.

The liquid supply nozzle 72 supplies a cleaning liquid to the surface (that is, a plane on which the metal film is formed) of the substrate W. The liquid supply nozzle 72 may include at least one of a pure water nozzle for supplying pure water and a chemical liquid nozzle for supplying a chemical liquid. When the liquid is supplied to the surface of the substrate W, the electric charge amount on the substrate W can be changed.

The charge amount adjustment apparatus 73 is similar to the charge amount adjustment apparatus 44 of FIG. 3A, and can increase or decrease the charge amount of the surface of the substrate W according to the control from the controller 75 described later.

The charge amount measuring instrument 74 is similar to the charge amount measuring instrument 45 of FIG. 3A, and measures the charge amount of the surface of the substrate W. The measured charge amount is transmitted to the controller 75.

The controller 75 is similar to the controller 46 of FIG. 3A, is coupled to the charge amount adjustment apparatus 73 and the charge amount measuring instrument 74, and controls the charge amount adjustment apparatus 73 according to the charge amount measured by the charge amount measuring instrument 74.

The internal configuration of the controller 75 is similar to that illustrated in FIG. 4. The processing operation of the controller 75 is similar to that illustrated in FIG. 5. The control by the controller 75 is desirably performed in a state where a liquid (for example, pure water) is supplied onto the substrate W. The charge amount on the substrate W changes from moment to moment due to the supply of the liquid, but the charge amount can be controlled in real time.

When the chuck of the substrate holding mechanism 71 is conductive, the chuck may be coupled to the ground terminal via a switch as in FIG. 7.

[Overall Operation of Substrate Processing Apparatus 100]

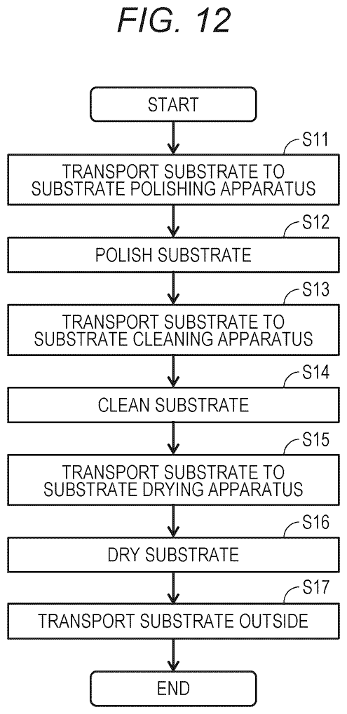

FIG. 12 is a flowchart illustrating the entire operation of the substrate processing apparatus 100.

First, the substrate transport apparatus 6 transports a substrate W to be processed to the substrate polishing apparatus 3 (step S11). Since the substrate W has not yet been polished, the substrate transport apparatus 6 may not adjust an electric charge amount.

Next, the substrate polishing apparatus 3 polishes the substrate W (step S12).

Next, the substrate transport apparatus 6 transports the substrate W after polishing from the substrate polishing apparatus 3 to the substrate cleaning apparatus 4 (step S13). The substrate transport apparatus 6 that performs this transport may be the one described in FIGS. 10A and 10B, and it is desirable to transport the substrate while adjusting the electric charge amount.

Next, the substrate cleaning apparatus 4 cleans the substrate W (step S14). The substrate cleaning apparatus 4 that performs this cleaning may be any of those described in FIGS. 3A, 3B, and 7, and it is desirable to perform cleaning while adjusting the electric charge amount.

Next, the substrate transport apparatus 6 transports the substrate W after cleaning from the substrate cleaning apparatus 4 to the substrate drying apparatus 5 (step S15). The substrate transport apparatus 6 that performs this transport may be the one described in FIGS. 10A and 10B, and it is desirable to transport the substrate while adjusting the electric charge amount.

Next, the substrate drying apparatus 5 cleans the substrate W (step S16). The substrate drying apparatus 5 that performs this drying may be the one described in FIG. 9, and it is desirable to perform the drying while adjusting the electric charge amount.

Next, the substrate transport apparatus 6 transports the substrate W after drying from the substrate drying apparatus 5 to the outside (step S17). Since the surface of the substrate W is in a dried state by the drying processing, the substrate transport apparatus 6 may not adjust the electric charge amount.

Since the charge amount of the substrate W fluctuates due to movement of the liquid (for example, pure water) on the substrate W, it is desirable to adjust the charge amount in each process (steps S13 to S16) from after the polishing to the drying.

According to the present embodiment described above, since the electric charge amount on the surface of the substrate W is appropriately adjusted, corrosion of the metal film formed on the surface of the substrate W can be suppressed.

Arbitrary part or all of the functional units described in the present specification may be implemented by a program. The program referred to in the present specification may be distributed by being non-temporarily recorded in a computer-readable recording medium, may be distributed via a communication line (including wireless communication) such as the Internet, or may be distributed in a state of being installed in an arbitrary terminal.

Based on the above description, a person skilled in the art may be able to conceive additional effects and various modifications of the present invention, but aspects of the present invention are not limited to the individual embodiments described above. Various additions, modifications, and partial deletions can be made without departing from the conceptual idea and spirit of the present invention derived from the contents defined in the claims and equivalents thereof.

For example, what is described in the present specification as a single apparatus (alternatively, a member, the same applies hereinafter) (including what is depicted in the drawings as a single apparatus) may be implemented by a plurality of apparatuses. Conversely, what is described in the present specification as a plurality of apparatuses (including what is depicted in the drawings as a plurality of apparatuses) may be implemented by one apparatus. Alternatively, some or all of the means and functions included in a certain apparatus may be included in another apparatus.

In addition, not all the matters described in the present specification are essential requirements. In particular, matters described in the present specification and not described in the claims can be regarded as arbitrary additional matters.

It should be noted that the applicant of the present invention is merely aware of the invention disclosed in the document in the column of “prior art document” in the present specification, and the present invention is not necessarily intended to solve the problem in the invention disclosed in the document. The problem to be solved by the present invention should be recognized in consideration of the entire specification. For example, in the present specification, in a case where there is a description that a predetermined effect is exhibited by a specific configuration, it can be said that the problem of reversing the predetermined effect is solved. However, such a specific configuration is not necessarily an essential requirement.

### DESCRIPTION OF REFERENCE NUMERALS

100 substrate processing apparatus
1 housing
2 load port
3, 3a to 3d substrate polishing apparatus
4, 4a, 4b substrate cleaning apparatus
41 substrate holding and rotating mechanism
42 cleaning liquid supply nozzle
43 cleaning member
44 charge amount adjustment apparatus
45 charge amount measuring instrument
46 controller
461 charge amount acquisitor
462 determiner
463 charge amount controller
47 switch
5 substrate drying apparatus
51 substrate holding and rotating mechanism
52 drying fluid supply nozzle
53 charge amount adjustment apparatus
54 charge amount measuring instrument
55 controller
6, 6a to 6d substrate transport apparatus
61 transport robot
62 arm
63 substrate holding mechanism
64 charge amount adjustment apparatus
65 charge amount measuring instrument
66 controller
7 substrate placing apparatus
71 substrate holding mechanism
72 liquid supply nozzle
73 charge amount adjustment apparatus
74 charge amount measuring instrument

1. A substrate cleaning apparatus comprising:
a substrate holding and rotating mechanism configured to hold and rotate a substrate;
a cleaning liquid supplier configured to supply a cleaning liquid to the substrate;
a cleaning member configured to come into contact with the substrate to clean the substrate;
a charge amount adjustment apparatus capable of increasing and decreasing a charge amount of the substrate;
a charge amount measuring instrument configured to measure the charge amount of the substrate; and
a controller configured to control the charge amount adjustment apparatus according to the charge amount measured by the charge amount measuring instrument.

2. The substrate cleaning apparatus according to claim 1, wherein the controller controls the charge amount adjustment apparatus such that the charge amount measured by the charge amount measuring instrument falls within a target range.

3. The substrate cleaning apparatus according to claim 2, wherein a lower limit value of the target range is higher than 0.

4. The substrate cleaning apparatus according to claim 2, wherein the target range is determined according to a type of a metal film formed on the substrate.

5. The substrate cleaning apparatus according to claim 2, wherein
the controller
determines whether the charge amount measured by the charge amount measuring instrument falls between a first threshold corresponding to the lower limit value of the target range and a second threshold corresponding to an upper limit value of the target range,
controls the charge amount adjustment apparatus to increase the charge amount of the substrate when it is determined that the charge amount is less than the first threshold, and
controls the charge amount adjustment apparatus to decrease the charge amount of the substrate when it is determined that the charge amount exceeds the second threshold.

6. The substrate cleaning apparatus according to claim 1, wherein the substrate holding and rotating mechanism has a non-conductive holding member that comes into contact with the substrate and holds the substrate.

7. The substrate cleaning apparatus according to claim 1, wherein
the substrate holding and rotating mechanism has a conductive holding member that comes into contact with the substrate and holds the substrate, and
the holding member is coupled to a reference potential terminal via a switch.

8. The substrate cleaning apparatus according to claim 7, wherein the controller controls on/off of the charge amount adjustment apparatus and the switch according to the charge amount measured by the charge amount measuring instrument.

9. The substrate cleaning apparatus according to claim 1, wherein the controller controls the charge amount adjustment apparatus in a state where the cleaning liquid is supplied and the cleaning member is cleaning the substrate.

10. A substrate drying apparatus comprising:
a substrate holding and rotating mechanism configured to hold and rotate a substrate;
a fluid supplier configured to supply a fluid for drying the substrate;
a charge amount adjustment apparatus capable of increasing and decreasing a charge amount of the substrate;
a charge amount measuring instrument configured to measure the charge amount of the substrate; and
a controller configured to control the charge amount adjustment apparatus according to the charge amount measured by the charge amount measuring instrument.

11. A substrate transport apparatus that transports a polished substrate, the apparatus comprising:
a substrate holding mechanism configured to hold the substrate;
a charge amount adjustment apparatus capable of increasing and decreasing a charge amount of the substrate;
a charge amount measuring instrument configured to measure the charge amount of the substrate; and
a controller configured to control the charge amount adjustment apparatus according to the charge amount measured by the charge amount measuring instrument.

12. The substrate transport apparatus according to claim 11, wherein
the substrate holding mechanism is provided in an arm that extends and contracts,
the charge amount adjustment apparatus is installed at a first position in which the charge amount of the substrate is increased and decreased in both a contracted state and an extended state of the arm, and
the charge amount measuring instrument is installed at a second position in which the charge amount of the substrate is measured in both the contracted state and the extended state of the arm.

13.-23. (canceled)
